(19) United States
(12) Patent Application Publication
(10) Pub. No.: US 2005/0276423 A1
(43) Pub. Date: Dec. 15, 2005

(54) Method and device for receiving and treating audiosignals in surroundings affected by noise

(76) Inventors: Roland Aubauer, Bocholt (DE); Ralf Kern, Bocholt (DE); Stefano Ambrosius Klinke, Dusseldorf (DE); Dieter Leckschat, Bocholt (DE)

Correspondence Address: BELL, BOYD & LLOYD, LLC, P. O. BOX 1135, CHICAGO, IL, 60690-1135, US

(21) Appl. No.: 09/937,022

(22) PCT Filed: Sep. 19, 2001
(86) PCT No.: PCT/DE00/00859

§ 371 Date: Dec. 3, 2001

(30) Foreign Application Priority Data
Mar. 19, 1999 (DE) 19912525.2
Jul. 23, 1999 (DE) 19934724.7

(51) Int. Cl. H04R 1/02; H04R 3/00; H03G 3/20

(52) U.S. Cl. 381/92; 381/91; 381/122; 381/57

(57) ABSTRACT

In order to record and to process audio signals with a good useful-signal to noise-signal ratio in acoustic noise conditions and with a good ratio between the direct sound and the reflected sound in an environment which in particular has no reverberation electrical signals produced by conversion of audio signals recorded by a predetermined microphone arrangement are processed in such a manner that, if the sound pressure levels at the microphones in the microphone arrangement are the same, electrical signals which are produced by these microphones but are of different intensity—different sensitivities of the microphones—are automatically matched, without any manual matching procedures needed to be carried out individually and separately. A microphone arrangement is based on combining the characteristics of an array of microphones with those of a method for matching the sensitivity of microphones.

### BACKGROUND OF THE INVENTION

Previous methods and devices for recording and processing audio signals (for example speech and/or sound signals) in an environment filled with acoustic noise are based either on the use of a first-order directional microphone (gradient microphones) or on a microphone array having two or more individual microphones (for example ball microphones). In the latter case, additional digital filters are used to match the frequency responses of the microphones.

Both directional microphones and microphone arrays are covered by the generic term free-field microphones, whose directivity allows the useful sound and the acoustic noise to be separated, and whose output signals are added using the “delay and sum principle”.

Microphone arrays are arrangements of a number of microphones positioned physically separately, whose signals are processed such that the sensitivity of the overall arrangement is directional. The directivity results from the propagation time differences (phase relationships) with which a sound signal arrives at the various microphones in the array. Examples of this are so-called gradient microphones or microphone arrays which operate on the delay and sum beam-former principle. A problem that arises in the practical implementation of microphone arrays is the scatter, resulting from production tolerances, in the sensitivity and frequency response of the individual microphones used. The sensitivity in this case means the characteristic of a microphone to produce an electrical signal from a predetermined sound pressure level. The frequency response represents the way in which the sensitivity of the microphone varies with frequency. The tolerance band stated by the microphone manufacturers is typically between ±2 and ±4 dB. If these microphone characteristics differ within a microphone array, then this has a negative influence on the frequency response and the directional characteristic of the overall arrangement. As a rule, the frequency response has increased ripple, while the directivity is considerably reduced. In this context, Table 1 shows the reduction in the directivity index of a second-order gradient microphone (microphone array comprising two individual cardioid microphones) when the two individual microphones have different sensitivities. The directivity index in this case indicates the suppression of diffused incident sound compared to useful sound from the microphone major axis.

Until now, the sensitivity and the frequency response of the individual microphones in an array have had to be determined by acoustic measurement and have had to be matched to one another by suitable electrical amplifiers and filters. The measurement includes the stimulation of the microphone to be measured using a sound reference signal produced via a loudspeaker, and the recording of the electrical signals produced by the microphones. The gain factors and filter parameters required for matching are then calculated from the microphone signals, and set as appropriate.

The acoustic measurement of the microphone parameters involves considerable technical complexity and results in corresponding costs for the production of microphone arrays. Furthermore, the trimming process is carried out during the production of the microphone array, so that it is applicable only to this one operating situation. Other operating situations, for example different supply voltages or aging effects of the microphones, are ignored.

A gradient microphone system is known from U.S. Pat. No. 5,463,694, which is based on the idea that microphones essentially have the same frequency response and the same sensitivity. The term “sensitivity” means the characteristic of a microphone to produce a predetermined electrical signal from a predetermined sound pressure level.

### SUMMARY OF THE INVENTION

An advantage of the present invention is to record and to process audio signals with a good useful-signal to noise-signal ratio in acoustic noise conditions and with a good ratio between the direct sound and the reflected sound in an environment which in particular has no reverberation.

According to the invention, there is processing of electrical signals produced by conversion of audio signals recorded by a predetermined microphone arrangement in such a manner that, if the sound pressure levels at the microphones in the microphone arrangement are the same, electrical signals which are produced by these microphones but are of different intensity—different sensitivities of the microphones—are automatically matched, that is, without any manual matching procedures needing to be carried out individually and separately.

The invention, in this case, pertains to combining the characteristics of an array of microphones with those of a method for matching the sensitivity of microphones.

Advantages of this procedure involve simple implementation in conjunction with the (optimum) result achieved in the process and, a good relationship between the complexity of the microphone arrangement (arrays) and the result.

The result which can be achieved using the present invention is considerably better than the result which can be achieved by using U.S. Pat. No. 5,463,694. This is shown in the following table:

The table shows the relationship between the “difference between the sensitivity of the microphones (delta)” and the “directivity index”

| Delta (dB) | Directivity index (dB) |
|---|---|
| 0 | 8.7 |
| 1 | 8.4 |
| 2 | 8.1 |
| 3 | 7.8 |
| 4 | 7.5 |
| 5 | 7.2 |
| 6 | 6.9 |

Summary: The greater the difference between the sensitivity of the microphones, the poorer is the directivity index.

The method and the device of the invention allow an optimum directivity index to be achieved for the microphone arrangement for any environment filled with acoustic noise, since it always automatically matches the sensitivity of the microphones.

One parameter for assessing a directional microphone is the directivity index. The directivity index means the extent to which diffuse (omnidirectional) incident sound is suppressed in comparison to useful sound from the major axis. In this case, the directivity index is a logarithmic variable, and is therefore expressed in decibels.

The present invention preferably comprises an array of microphones and filters in order to match the sensitivity of the microphones and to achieve the desired array frequency response.

In comparison to known microphone arrays, which require complicated digital filters in order to match the frequency responses of the microphones, the inventive method and device require only the sensitivity to be matched. Furthermore, this can be achieved either by a simple digital filter, or by an analog circuit.

With the inventive array, in which two simple directional microphones are used, directivity indexes are achieved which cannot be achieved with a single directional microphone. An array of ball microphones can achieve this result, but only by using more than two microphones to form the array. Furthermore, preferably, a filter is required for each microphone in order to match the frequency responses of the various microphones.

In order to match the sensitivity of the microphones, the microphones should be stimulated using a sound preferably source which is arranged at right angles to the axis of the microphones, in order to calculate the sensitivity correction. However, this is not always feasible in practice.

Alternatively, it is also possible to match the sensitivity independently of the position of the sound source. For example, when the sound source has only low-frequency components whose wavelengths are much longer than the distance between the microphones. In a microphone arrangement having two microphones, the wavelength should, for example, be greater than twice the distance between the microphones, while the wavelength for a microphone arrangement having more than two microphones should be greater than the sum of the distances between the individual microphones.

Furthermore, the microphones are preferably positioned in pairs such that their major axes lie on a common axis. However, deviations from this are also possible with regard to a tilt or adjustment angle, which can vary, for example, in the range between 0° and 40°, and with respect to an offset distance which, for example, is less than or equal to the distance between the microphones. In all these different situations, there is preferably one reference microphone with a reference major axis with respect to which each of the other microphones in the microphone arrangement is arranged at an adjustment angle to the major axis and at an offset distance from it.

The signals from the microphones are processed, for example, by a block in order to match the sensitivity of the microphones. The sum and the difference are then formed from the two signals, and combined to form a linear combination in order to obtain a signal with a higher-order directional characteristic than that of the two microphones in the array.

The signal is then processed using a filter in order to achieve the desired array frequency response and sensitivity.

Furthermore, it is advantageous if the microphone arrangement is a second-order gradient microphone (quadrupole microphone) arranged on an “acoustic boundary surface since this improves the ratio between the signal and the self-noise. In acoustics, an “acoustic boundary surface” is a hard surface, for example a table in a room, a window pane or the roof in a car etc. In this case, the ratio between the useful signal and the environmental noise is furthermore increased when sound is recorded in situations with high environmental noise, for example in vehicles or in public spaces. The subjective comprehensibility of recorded speech is thus improved in an environment with reverberation, for example in spaces with highly reflective walls (car, telephone cubicle, church, etc.).

The quadrupole microphone consists of a combination of two first-order gradient microphones with a cardioid characteristic, whose output signals are subtracted from one another. This measure increases the directivity index from 4.8 to 10 dB. The directivity index in this case indicates the gain with which the useful signal incident on the microphone major axis is amplified in comparison to the diffuse incident noise signal. Suitable arrangement of the individual microphones in the quadrupole microphone on a boundary surface improves the useful signal sensitivity of the microphone by a further 6 dB, and significantly improves the useful signal to self-noise ratio of higher-order gradient microphones, which is in principle low in the lower frequency range.

A significant advantage of the present invention is that the complexity involved in achieving improved useful signals is small in comparison to that of previous solutions. At the same time, the external dimensions of the boundary surface quadrupole microphone are less than with known arrangements of comparable directivity. The proposed arrangement avoids interference between the incident direct sound and the sound which is reflected by the boundary surface and can interfere with the directivity of a microphone close to a boundary surface.

The boundary-surface construction of the gradient microphone raises the microphone useful signal incident on the major axis by 6 dB with respect to the microphone self-noise.

Higher-order gradient microphones constructed with a boundary surface can be used sensibly wherever high-quality recording of acoustic signals is required in a noisy environment. In addition to high noise signal suppression, the high directivity of the microphone also achieves considerable suppression of reverberation in rooms, so that this considerably improves the capability to understand speech, even in quiet rooms. Examples for the use of the proposed invention include hands-free devices for telephones and automatic voice recognition systems, as well as conference microphones.

Additional features and advantages of the present invention are described in, and will be apparent from, the Detailed Description of the Preferred Embodiments and the Drawings.

### BRIEF DESCRIPTION OF THE FIGURES

FIG. 1 is a schematic diagram of a microphone array according to the present invention.

FIG. 2 is a schematic diagram of another microphone array according to the present invention.

FIG. 3 is a schematic diagram of an automatic microphone sensitivity trimming for n microphones in an array.

FIG. 4 is a schematic diagram of an automatic microphone sensitivity trimming for two microphones, with the signal levels of both microphones being regulated.

FIG. 5 is a schematic diagram showing a trimming process according to the present invention.

FIG. 6 is a schematic diagram of a trimming apparatus according to the present invention.

FIG. 7 is a circuit diagram for sensitivity and frequency response control of microphones according to the invention.

FIG. 8 is another circuit diagram for sensitivity and frequency response control of microphones according to the present invention.

### DETAILED DESCRIPTION OF THE INVENTION

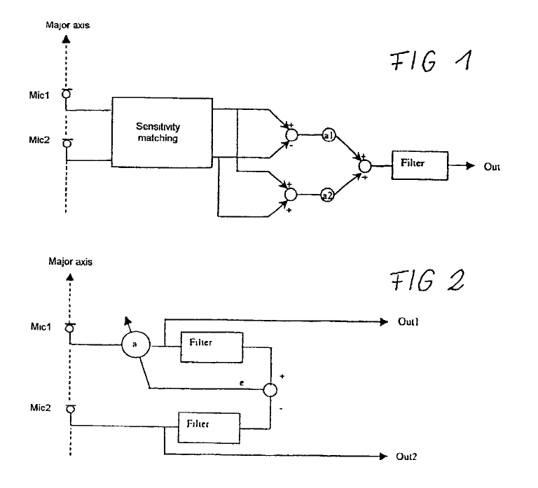

The way in which the sensitivity trimming is carried out is shown in FIGS. 1 and 2. If the two microphones have approximately the same frequency response, sensitivity trimming in a restricted frequency range is sufficient to achieve the desired directivity over the entire transmission band. In practical situations, the condition of “equal frequency response” is satisfied to a good approximation.

The filter illustrated in FIG. 2 may advantageously be in the form of a low-pass filter with a cut-off frequency of, for example, 100 Hz.

The possible applications for a second-order gradient microphone include all situations where good speech transmission is required in noisy surroundings. For example, this may be a microphone for a hands-free system in a car, or the microphone for a voice recognition system operating in the hands-free mode.

Automatic Trimming of Microphone Sensitivity

The present invention can address the problem of microphone sensitivity trimming by automatic trimming of the microphone signal levels during operation of the microphones in an array. In this case, the existing environmental noise level or useful signal level is sufficient. The microphone signal levels and amplitudes recorded by the microphones are measured and are matched to one another independently of their respective phases. In this case, it must be assumed that the sound pressure levels arriving at the microphones are virtually the same, or that the discrepancies are considerably less than the microphone sensitivity tolerance. This condition is satisfied when the distance between the sound source which dominates the sound level and the microphone array is considerably greater than the distance between the microphones to be trimmed, and no pronounced space modes occur. The signal levels can be measured by any type of envelope curve measurement or by real root-mean-square value measurement. The time constant for this measurement must in this case be longer than the maximum signal propagation time between the microphones to be trimmed. The sensitivity trimming can be carried out by amplification or attenuation in the opposite sense to the discrepancy between the signal levels.

FIG. 3 shows the block diagram of the automatic microphone sensitivity trimming for n microphones in an array. Microphone 1 is in this case the reference microphone, to whose microphone signal level the levels of the other microphones 2 to n are matched. The circuit diagram is composed of blocks whose gain or attenuation is controllable and units for signal level measurement. The measured signal levels are used to produce difference or error signals eₙ, which are used as the control variable for the variable amplifiers or attenuators. Overall, there are n−1 regulators, whose reference variable is the signal level of the reference microphone. In order to satisfy the distance condition mentioned in the previous paragraph, adjacent microphones can also be trimmed in pairs (not shown in FIG. 3).

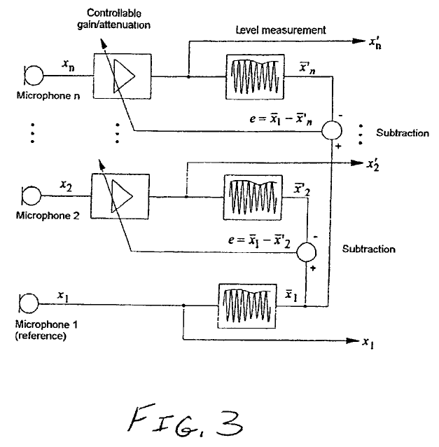

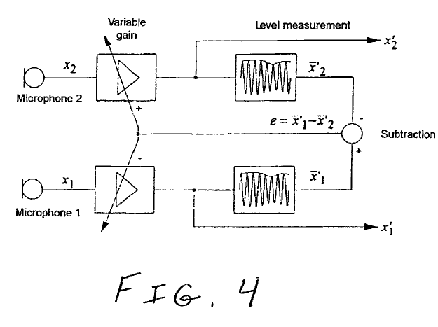

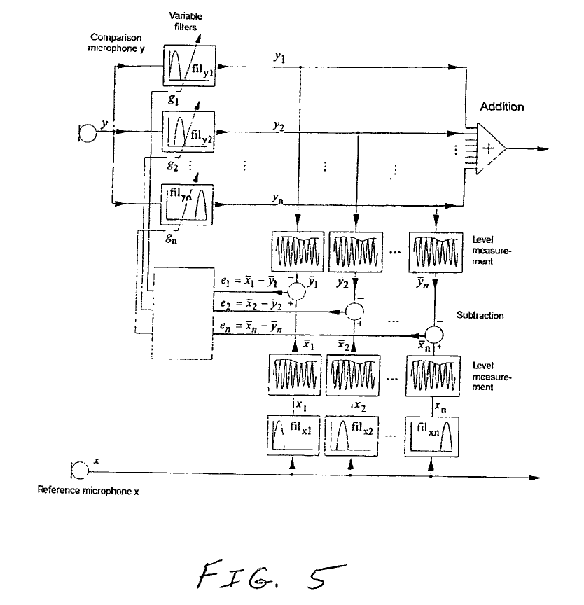

FIG. 4 shows the block diagram of the automatic microphone sensitivity trimming for two microphones, with the signal levels of both microphones being regulated. The advantage of this embodiment over an embodiment with an unregulated reference microphone as shown in FIG. 3 is that there is less variance between the output levels, since it is possible to use the mean sensitivity of the microphones for regulation.

The automatic microphone trimming proposed here can be implemented easily in terms of circuitry and requires no further trimming steps, such as complex acoustic trimming. This results in clear cost advantages even for small microphone array quantities. Furthermore, the method allows continuous trimming, so that it is also possible to take account of changes in the microphone sensitivity occurring over time.

Automatic Trimming of the Microphone Frequency Response

Automatic microphone frequency response trimming is a generalization of microphone sensitivity trimming. For frequency trimming, it must be assumed that the spectral distribution of the sound arriving at the microphones in the frequency ranges in which compensation is to be carried out is similar, and that any discrepancies are well below the microphone frequency response tolerance bands. This condition is once again satisfied for a sound source located well away in comparison to the distance between the microphones (see the distance condition, further above).

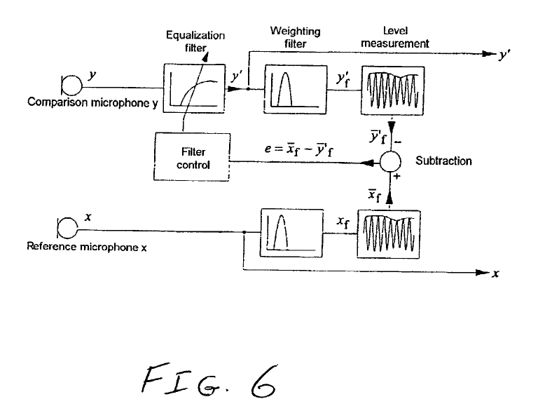

The trimming process is carried out in sub-bands of the microphone transmission frequency band, and can be carried out by equalization using either appropriate analog or digital filters. In the most obvious case, this is a filter structure comprising bandpass filters connected in parallel (as shown in FIG. 5) or in series, and whose gains can be controlled independently of one another. The sum frequency response of the filters for the unregulated reference microphone (FIG. 5 filₓ₁, filₓ₂ . . . filₓₙ) is flat in the desired transmission frequency band. The frequency response of the comparison microphone is compared to that of the reference microphone by raising or lowering (amplifying or attenuating) the filter sub-bands (fil_{y1}, fil_{y2} . . . fil_{yn}). The control signals g₁, g₂, gₙ required to do this are derived directly from the error signals (g₁˜e₁, g₂˜e₂ . . . gₙ˜eₙ) obtained for the individual frequency bands. A large number of bandpass filters are usually required for precise trimming.

The complexity of the filter structure can be reduced considerably if those microphone parameters which are dominant in specific frequency bands, such as the configuration of the sound inlet opening, the front/back volume, the diaphragm flexibility and their electrical equivalent circuits are known, and discrepancies between microphones can be traced back to changes in individual parameters. The trimming process can be carried out with comparatively little complexity by means of appropriate equalization filters, which specifically counteract these discrepancies.

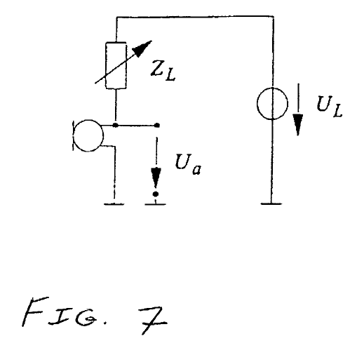

FIG. 6 shows the block diagram of a trimming apparatus which comprises a controllable equalization filter, weighting filters and level measurement units. The equalization filter is once again actuated via the difference signal e from the level measurement units, in which case both the amplitude and the phase frequency response are generally varied.

The advantages mentioned for sensitivity trimming also apply to automatic trimming of the microphone frequency response.

Simple Control of the Sensitivity of Microphones with an Integrated Amplifier, Whose Operating Point can be Adjusted by Means of External Circuitry, for Example a Field-Effect Transistor Preamplifier (Feet Preamplifier)

Virtually all the microphone capsules used currently in telecommunications and consumer applications are electorate transducers with an integrated field-effect transistor preamplifier. These preamplifiers are used to reduce the very high microphone source impedance and to amplify the microphone signal. Generally, this represents the source circuit of a field-effect transistor. The operating point of the transistor, and hence the sensitivity of the microphone as well, can be varied by varying the supply impedance and the supply voltage. The microphone frequency response can be varied, provided not just real but also complex supply impedances are acceptable.

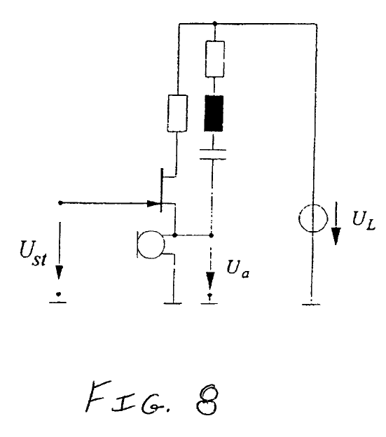

FIGS. 7 and 8 each show a circuit for sensitivity and frequency response control of electronic microphones, which does not require any external, controllable amplifiers or attenuators. An implementation provides sensitivity and frequency response control via the microphone supply voltage U_{L}, which, in the case of automatic sensitivity trimming or matching, can be derived directly from the difference signal between the measured sound levels or signal levels U_{L}=(v·eₙ)+U₀ (v in this case denotes a gain factor and U a constant voltage parameter, for example the output voltage before sensitivity and frequency matching). The control range of the microphone sensitivity by varying the microphone supply voltage is up to 25 dB, depending on the supply impedance (see Table 2).

Alternatively, it is also possible to provide sensitivity and frequency response control in such a manner that the microphone supply impedance Z_{L} with a control voltage U_{ST} which, in the case of automatic sensitivity and frequency response trimming and matching, can be derived directly from the difference signal between the measured sound levels and signal levels U_{ST}≈((v·eₙ)+U₀′) (v in this case denotes a gain factor and U₀′ a constant voltage parameter, for example the output voltage before sensitivity and frequency response matching).

The supply impedance Z_{L} can be controlled electronically by means of a controlled field-effect transistor for real values, and by means of a gyrator circuit for complex values. The control range of the microphone sensitivity via the supply impedance is up to 10 dB, depending on the microphone supply voltage (see Table 2).

One advantage of this type of sensitivity and frequency response control is that the circuit complexity is minimized, as well as the costs associated with it. The control range is sufficiently high for most applications.

Accordingly, to an embodiment, the present invention provides sensitivity and frequency response trimming by the separation of amplitude and phase information from the sound arriving at the microphones, which allows automatic trimming while microphones are being operated in an array. While the phase relationship is used to form the directional characteristic of an array, the amplitude relationship is available for trimming of the microphone sensitivities and of the amplitude frequency responses. Production tolerances relating to these microphone parameters can thus be compensated for, so that the desired frequency response and the directional characteristic of the overall arrangement are obtained.

According to an embodiment, the present invention provides sensitivity control of microphones having an integrated FET preamplifier by the use of the supply voltage or of the supply resistance to vary the FET operating point, and hence the gain of the FET preamplifier.

The inventive microphone trimming can be used for all multiple microphone arrangements whose directional sensitivity is obtained by using the phase relationships between the individual microphone signals. These microphone arrangements can sensibly be used wherever high-quality recording of acoustic signals is required in a noisy environment. The directional characteristic of these arrangements in this case allows acoustic noise (environmental noise, reverberation) away from the microphone major axis to be attenuated, and adjacent sound sources (other speakers) to be separated. By avoiding complex acoustic trimming, automatic microphone trimming allows considerable cost savings during production, and thus also makes it possible to use microphone arrays in consumer applications, for example in hands-free devices for communications terminals or for equipment voice control. Further applications of microphone arrays in which the invention can sensibly be used are conference microphones.

The trimming invention has been implemented in a simple electronic circuit and has been tested using a second-order gradient microphone. Gradient microphones are formed by interconnecting two cardioid microphones, whose sensitivity is automatically trimmed by means of the circuit. The sensitivity control for the microphone to be trimmed is carried out using the principles of the present invention. Microphone trimming operates even at low environmental noise levels (room volume) and is independent of the sound incidence direction.

The sensitivity control for microphones with a built-in FET preamplifier can also advantageously be used for automatic control of microphone signal levels. These circuits are generally referred to as automatic gain control circuits. Practical applications for such circuits include all consumer equipment having a microphone recording channel (cassette recorders, dictation systems, hands-free telephones, etc.).

Although the present invention has been described with reference to specific embodiments, those of skill in the art will recognize that changes may be made thereto without departing from the spirit and scope of the invention as set forth in the hereafter appended claims.

1-35. (canceled)

36. A method for recording and processing audio signals from a sound source in an environment having acoustic noise, comprising the steps of:
(a) arranging first and second microphones with a predetermined distance between the microphones;
(b) arranging the first and second microphones with respect to a major axis defined by the first microphone in such a manner that the second microphone is arranged at a predetermined angle to the major axis and/or at a predetermined offset distance from the major axis; and
(c) processing first and second electrical signals respectively produced by the first and second microphones by automatically matching the first and second electrical signals which have different sensitivities and/or different frequency responses.

37. The method as claimed in claim 36 wherein the arranging steps further comprise arranging a plurality of second microphones relative to the first microphone, each second microphone producing a second electrical signal, and wherein the processing step further comprises processing the first electrical signal which each second electrical signal in pairs by automatically matching respectively difference sensitivities and/or frequency responses in the electrical signals produced by the microphones.

38. The method as claimed in claim 37, wherein when matching for difference sensitivities, further comprising the steps of:
(a) filtering each pair of the first electrical signal and the second electrical signal;
(b) forming signal level differences from the filtered electrical signals; and
(c) varying the respective signal levels of the unfiltered electrical signals as a function of the signal level differences until the signal level differences each essentially have a value “0”.

39. The method as claimed in claim 38, further comprising the steps of:
(a) forming a sum signal and a difference signal for each pair of first and second signals from the unfiltered electrical signals;
(b) forming a joint signal from the respective sum signals and difference signals in order to achieve a higher-order directional characteristic by forming linear combinations and/or propagation time delays based on the delay and sum principle; and
(c) filtering the joint signal in order to achieve a desired frequency response and a desired sensitivity.

40. The method as claimed in claim 38, further comprising the step of filtering each pair of first and second electrical signals when the major axis is arranged essentially at right angles to the sound source.

41. The method as claimed in claim 38, further comprising the step of low-pass filtering each pair of first and second electrical signals when the major axis is not arranged essentially at right angles to the sound source, and when only first and second microphones are arranged, defining a wavelength of the low-pass-filtered frequencies as greater than twice the distance between the first and second microphones, and when the first microphone and the plurality of second microphones are arranged, defining a wavelength of the low-pass-filtered frequencies as greater than a sum of the distances between the individual microphones.

42. The method as claimed in claim 37, wherein when matching different sensitivities, further comprising the steps of:
(a) measuring signal levels of both the first electrical signal and the second electrical signal for each pair of first and second electrical signals;
(b) forming signal level differences from the measured signal levels; and
(c) varying the respective signal levels of the electrical signals as a function of the signal level differences until the signal level differences each essentially have a value “0”.

43. The method as claimed in claim 42, further comprising the steps of:
(a) forming a sum signal and a difference signal for each pair of first and second electrical signals;
(b) forming a joint signal from the respective sum signals and difference signals in order to achieve a higher-order directional characteristic by forming linear combinations and/or propagation time delays based on a delay and sum principle; and
(c) filtering the joint signal in order to achieve a desired frequency response and desired sensitivity.

44. The method as claimed in claim 37, wherein when matching different frequency responses, further comprising the steps of:
(a) filtering the first electrical signal and the second electrical signal n times where nεN;
(b) measuring signal levels of both the filtered first electrical signal and the filtered second electrical signal;
(c) forming signal level differences from the measured signal levels of the filtered electrical signals; and
(d) varying the respective signal levels relating to the filtering of the electrical signals as a function of the signal level differences until the signal level differences each essentially have a value “0”.

45. The method as claimed in claim 44, wherein the first electrical signal and the second electrical signal are bandpass-filtered n times where nεN.

46. The method as claimed in claim 44 further comprising the steps of:
(a) forming a sum signal and a difference signal for each pair of the first electrical signal or first total signal of the n-times filtered first electrical signal, and a second total signal of the n-times filtered second electrical signal;
(b) forming a joint signal from the respective sum signals and difference signals in order to achieve a higher-order directional characteristic by forming linear combinations and/or propagation time delays based on the delay and sum principle; and
(c) filtering the joint signal in order to achieve a desired frequency response and a desired sensitivity.

47. The method as claimed in claim 37, wherein when matching different frequency responses, further comprising the steps of:
(a) filtering at least one of the first electrical signal and the second electrical signal for equalization;
(b) filtering the first electrical signal and the second electrical signal for weighting;
(c) measuring signal levels of both the weighted first electrical signal and the weighted second electrical signal;
(d) forming signal level differences from the measured signal levels of the weighted electrical signals; and
(e) varying the respective signal levels relating to the equalization filtering of the electrical signals as a function of the signal level differences until the signal level differences each essentially have a value “0”.

48. The method as claimed in claim 47, further comprising the steps of:
(a) forming a sum signal and a difference signal for each pair of first and second signals from the first electrical signal or from the equalized first electrical signal, and from the equalized second electrical signals;
(b) forming a joint signal from the respective sum signals and difference signals in order to achieve a higher-order directional characteristic by forming linear combinations and/or propagation time delays based on the delay and sum principle; and
(c) filtering the joint signal in order to achieve a desired frequency response and desired sensitivity.

49. The method as claimed in claim 36, wherein the step of arranging first and second microphones further comprises arranging two directional or gradient microphones.

50. The method as claimed in claim 37, wherein arranging the first microphone and the plurality of second microphones comprises the step of arranging three ball microphones.

51. The method as claimed in claim 36, wherein the predetermined angle is in the range of from about 0° to about 40°.

52. The method as claimed in claim 36, wherein the offset distance is less than or equal to the distance between the first and second microphones.

53. The method as claimed in claim 36, wherein the first and second microphones are arranged on an acoustic boundary surface.

54. A device for recording and processing audio signals from a sound source in an environment having acoustic noise, comprising:
(a) a microphone arrangement having at least two microphones arranged in pairs with a predetermined distance between the microphones in each a pair of microphones;
(b) a first microphone and at least one second microphone of the at least two microphones being arranged with respect to a major axis, which is defined by the first microphone, in such a manner that the at least one second microphone is arranged at a predetermined angle to the major axis and/or at a predetermined offset distance from the major axis;
(c) a first filter which filters a first electrical signal produced by the first microphone and a second electrical signal produced by the second microphone, the first and second signals having different sensitivities and/or frequency responses;
(d) means for forming signal level differences in pairs from the filtered electrical signals; and
(e) a controller connected to the means for forming signal level differences which at least partially varies the respective signal levels of the unfiltered electrical signals as a function of the signal level differences, until the signal level differences each essentially have a value “0”.

55. The device claimed in claim 54, further comprising:
(a) sum formation means which forms sum signals and difference signals in pairs from the unfiltered electrical signals;
(b) means for forming linear combinations and/or propagation time delays which each form a joint signal from the respective sum signals and difference signals in order to achieve a higher-order directional characteristic based on the delay and sum principle; and
(c) a second filter which filters the joint signal in order to achieve a desired frequency response and a desired sensitivity.

56. The device as claimed in claim 55, wherein the first filter is one of a low-pass, high-pass or bandpass filter, when the sound source is arranged essentially at right angles to the major axis.

57. The device as claimed in claim 56, wherein the first filter is a low-pass filter when the sound source is not arranged essentially at right angles to the major axis and a wavelength of the low-pass-filtered frequencies with the microphone arrangement having two microphones is greater than twice the distance between the microphones, and, with the microphone arrangement having more than two microphones; is greater than the sum of the distances between the individual microphones.

58. A device for recording and processing audio signals from a sound source in an environment having acoustic noise, comprising:
(a) a microphone arrangement having at least two microphones arranged in pairs with a predetermined distance between the microphones in each pair of microphones;
(b) a first microphone and at least one second microphone of the at least two microphones being arranged with respect to a major axis, which is defined by the first microphone, in such a manner that the at least one second microphone is arranged at a predetermined angle to the major axis and/or at a predetermined offset distance from the major axis and the first microphone;
(c) means for measuring signal levels from a first electrical signal produced by conversion by the first microphone and from a second electrical signal produced by conversion by each second microphone, with the signals having different sensitivities;
(d) means for forming signal level differences in pairs from the measured electrical signals; and
(e) a controller connected to the means for forming signal level differences which at least partially varies the electrical signals as a function of the signal level differences relating to the respective signal level, until the signal level differences each essentially have a value of “0”.

59. The device as claimed in claim 58, further comprising:
(a) a sum formation means which forms sum signals and difference signals in pairs from the electrical signals;
(b) means for forming linear combinations and/or propagation time delays which each form a joint signal from the respective sum signals and difference signals in order to achieve a higher-order directional characteristic based on the delay and sum principle; and
(c) a filter which filters the joint signal in order to achieve a desired frequency response and a desired sensitivity.

60. A device for recording and processing audio signals from a sound source in an environment having acoustic noise, comprising:
(a) a microphone arrangement having at least two microphones arranged in pairs with a predetermined distance between the microphones in each pair of microphones;
(b) a first microphone and at least one second microphone of the at least two microphones being arranged with respect to a major axis, which is defined by the first microphone, in such a manner that the second microphone is arranged at a predetermined angle to the major axis and/or at a predetermined offset distance from the major axis and the first microphone;
(c) filters which filter a first electrical signal produced by conversion by the first microphone and a second electrical signal produced by conversion by each second microphone, with the signals having different frequency responses n times where nεN;
(d) means for measuring signal levels of the filtered first and second signals;
(e) means for forming signal level differences in pairs from the filtered electrical signals; and
(f) a controller connected to the means for forming signal level differences which at least partially varies the respective signal levels of the filtering of the electrical signals as a function of the signal level differences until the signal level differences each essentially have a value “0”.

61. The device as claimed in claim 60, wherein the filter is a bandpass filter.

62. The device as claimed in claim 61, further comprising:
(a) sum formation means which forms sum signals and difference signals in pairs from the first electrical signal or from a first total signal of the n-times filtered first electrical signal, and from a second total signal of the n-times filtered second electrical signal;
(b) means for forming linear combinations and/or propagation time delays which each form a joint signal form the respective sum signals and difference signals in order to achieve a higher-order directional characteristic based on the delay and sum principle; and
(c) a filter which filters the joint signal in order to achieve desired frequency response and a desired sensitivity.

63. A device for recording and processing audio signals from a sound source, in an environment having acoustic noise, comprising:
(a) a microphone arrangement having at least two microphones arranged in pairs with a predetermined distance between the microphones in each pair of microphones;
(b) a first microphone and at least one second microphone of the at least two microphones being arranged with respect to a major axis, which is defined by the first microphone, in such a manner that the second microphone is arranged at a predetermined angle to the major axis and/or at a predetermined offset distance from the major axis and the first microphone;
(c) equalization filters which filter a first electrical signal produced by conversion by the first microphone and a second electrical signal produced by conversion by each second microphone, with the signals having different frequency responses;
(d) weighting filters which filter the first electrical signal and the second electrical signal;
(e) means for measuring signal levels of the filtered first electrical signal and of the filtered second electrical signal;
(f) means for forming signal level differences in pairs from the filtered electrical signals; and
(g) a controller connected to the means for forming signal level differences which at least partially varies the respective signal levels of the equalization filtering of the electrical signals as a function of the signal level differences until the signal level differences each essentially have a value “0”.

64. The device as claimed in claim 63, further comprising:
(a) sum formation means which forms sum signals and difference signals in pairs from the first electrical signal or from the equalized first electrical signal, and from the equalized second electrical signal;
(b) means for forming linear combination and/or propagation time delays which each form a joint signal from the respective sum signals and difference signals in order to achieve a higher-order directional characteristic based on the delay and sum principle; and
(c) a filter which filters the joint signal in order to achieve a desired frequency response and a desired sensitivity.

65. The device as claimed in claim 54, wherein if the microphone has an integrated amplifier having an operating point which can be adjusted by external circuitry, the controller is designed in such a manner that
(a) sensitivity and/or the frequency response can be controlled via a microphone supply voltage which is obtained from the sum of a constant voltage and the product of a signal level difference signal and a gain factor, or
(b) a microphone feed impedance can be adjusted via a physical control variable, which is proportional to the product of a signal level difference signal and a gain factor, supplemented by a constant variable, in such a manner that the sensitivity and/or frequency response are controllable.

66. The device as claimed in claim 54, wherein the microphone arrangement has two directional or gradient microphones.

67. The device as claimed in claim 54, wherein the microphone arrangement has three ball microphones.

68. The device as claimed in claim 54, wherein the angle is in the range of from about 0° to about 40°.

69. The device as claimed in claim 54, wherein the offset distance is less than or equal to the distance between the microphones.

70. The device as claimed in claim 54, wherein the microphone arrangement is arranged on an acoustic boundary surface.
